(19) United States
(12) Patent Application Publication
(10) Pub. No.: US 2019/0120923 A1
(43) Pub. Date: Apr. 25, 2019

(54) METHOD FOR GENERATING POSITRON-EMISSION TOMOGRAPHY (PET) IMAGES

(71) Applicant: Bruker BioSpin MRI GmbH, Ettlingen (DE)

(72) Inventors: Arno NAUERTH, Erlenbach (DE); Michael HEIDENREICH, Karlsruhe (DE)

(21) Appl. No.: 15/792,386

(22) Filed: Oct. 24, 2017

(51) Int. Cl. G01R 33/567; G01R 33/563; G06T 11/00

(52) U.S. Cl. CPC G01R 33/5676; G01R 33/56308; G06T 2207/10088; G06T 2207/10104; G06T 11/003

(57) ABSTRACT

A method for generating positron-emission tomography images of at least one body having a target region which is in an anatomic motion that includes a repetitive motion pattern with a motion repetition rate. PET data is acquired by performing a PET measurement; motion states are determined during the PET acquisition period; the determined motion states are assigned to acquisition times; and PET images are reconstructed from selected PET data. During the PET-acquisition period, a sequence of individual MR-measurements on the body is performed at a MR-repetition rate higher than the motion-repetition rate, wherein nuclear spins of the body are excited during the sequence of individual MR-measurements at navigator times. Navigator signals are determined, each navigator signal being indicative of a motion state of the motion pattern at the navigator time. The motion states are determined by analyzing the navigator signals.

### FIELD OF THE INVENTION

The invention concerns a method for generating positron-emission tomography (PET) images of at least one body having a target region, which is in an anatomic motion comprising a repetitive motion pattern with a motion repetition rate, in particular cardiac and/or respiratory motion, the method comprising:
acquiring PET-data by performing a PET-measurement with a PET device during a PET-acquisition period;
determining motion states of the body during the PET-acquisition period;
assigning the determined motion states to PET-data acquired at acquisition times; and
reconstructing PET-images from selected PET-data.
   Imaging methods, such as MRI, PET, CT etc. require image reconstruction using image data acquired during an acquisition period. Imaging of living bodies is difficult, since motion of the body or parts of the body (in particular cardiac or respiratory motion) may reduce the resolution of the images.

### BACKGROUND

Imaging methods according to the state of the art therefore determine the motion states of the target region to be imaged. The reconstruction is carried out by using image data, which have been acquired during one or more motion state(s) of interest.

DE 10 2005 030 162 B3 discloses a method for generating MR (magnetic resonance) images of an object with a repetitive motion pattern. During the MR-measurements, the MR device further acquires navigator signals, which are indicative for the motion state of the motion pattern of the target region. An analogue PET-imaging method, in which navigator signals are obtained from PET-data, is not possible due to the different acquisition principles. Therefore, conventional PET methods use external trigger devices with pressure cushions and ECG electrodes in order to determine the respiratory and cardiac motion states of the body to be imaged (see for example Schafers at al. “Gated listmode acquisition with the quadHIDAC animal PET to image mouse hearts” Z Med Phys. 2006; 16(1):60-6). However, the cabling and especially attaching the ECG electrodes to the animals is very time consuming and prone to errors and malfunctions.

### SUMMARY

It is an object of the invention to provide a method for PET imaging, which reliably allocates the recorded PET data with the associated motion states with reduced errors and malfunction within an optimized period of time.

The invention according to one formulation provides that during the PET-acquisition period, a sequence of individual MR-measurements on the body is performed by an MR device at an MR-repetition rate higher than the motion-repetition rate, wherein nuclear spins of the body are excited during the sequence of individual MR-measurements at navigator times. With the individual MR-measurements, navigator signals are determined, each navigator signal being indicative for a motion state of the motion pattern at the navigator time. The motion states are determined by analyzing the navigator signals. The acquisition times to which the motion states are assigned correspond with the navigator times.

The body to be imaged is preferably a living organism, e.g. mouse, rat or human patient. According to the invention, the body comprises a target region to be imaged, in which flow and/or motion takes place (e.g. cardiac motion due to heartbeat, blood flow or respiratory motion due to breathing). Thus, objects (e.g. organs or blood) within the target region are moving relative to other elements within the target region, while the bodies as a whole may remain essentially stationary.

The anatomic motions show a repetitive motion pattern with recurrent motion phases (e.g. systole, diastole, inhalation, exhalation) or a superimposition of several repetitive motion patterns (e.g. superimposition of cardiac and respiratory motion). Typical motion-repetition rates are 10-100 respirations per minute (mice/rats: ca. 50, humans: ca. 15 respirations per minute) and 30-600 heartbeats per minute (mice: ca. 500, rats: 350, humans: ca. 60 heartbeats per minute, newts ca. 40 heartbeats per minute). The frequencies, with which the motion patterns are repeated, and the amplitudes of the motions may vary, i.e. the motions do not need to be exactly periodic.

A motion state may comprise a snapshot of the motion (e.g. end systole, end diastole, breathing space), but can also comprise a longer part of a motion phase (comprising more than only one single snapshot of the motion).

According to the invention, MR-data (navigator signals acquired from MR-measurements) are used to determine motion states of a body, which is imaged by PET, wherein the PET-image-data are acquired independently and in parallel to the MR-data. Motion states of the body/target region are determined by analyzing the navigator signals.

PET-image-data of the bodies are acquired by carrying out PET-measurements at acquisition times (points in time of the acquisition period). According to the invention, the motion states are assigned to acquisition times (and thereby are assigned to PET-data acquired at the acquisition times). Therefore, the navigator signals for the bodies are to be acquired within the duration of the same acquisition period. The assignment is realized through MR-data (more precisely through the navigator signals) obtained from the sequence of individual MR-measurements. An assignment takes place in case the acquisition time corresponds to the navigator time (plus/minus a specific interval where appropriate).

In general, the motion pattern (sequence of motion phases) of the anatomic motion is known. If the navigator signal does not comply with the expected motion pattern, the navigator signal can be discarded and no assignment to the image-data is carried out for the corresponding navigator time (point in time at which the respective individual MR-measurements is performed (time of excitation)).

For assignment of motion states to PET-data, information concerning the navigator times and the assigned motion states is sent to the PET-device. PET-data, acquired at the navigator times (plus/minus a specific interval, where appropriate) are linked with the corresponding motion state, e.g. by assigning an index (which is indicative for the motion state) to the PET-data. Now PET-images can be generated by selecting PET-data for PET-image reconstruction, which are linked to the same motion state or to selected motion states (predetermined motion states of interest).

The navigator signals are acquired from navigator-regions of the bodies. The navigator regions may correspond to the target regions, but can also be different from the target regions as long as the motion of the target region influences the navigator signal and the navigator signal is indicative for the motion state of the motion pattern of the target region. Thus, the dynamics associated with the target region are recorded by the navigator signal.

The navigator signal is a contiguous region of time-sequential data points of an MR-signal acquired during an individual MR-measurement. During the sequence of individual MR-measurements, the nuclear spins of each body are excited repeatedly. An individual MR-measurement comprises a gradient sequence, excitation, spatial encoding (optional), and detection/reading. Typical MR-repetition rates to be applied are 2000-15000 measurements per minute.

Navigator signals of a sequence of individual MR-measurements are determined during the same encoding state (i.e. by applying the same gradient sequence during each individual measurement, in which navigator signals are determined).

By determining motion states from navigator signals acquired by an MR device and by linking information concerning the determined motion states to PET-data, high quality PET images can be obtained with reduced efforts (no breathing monitors and ECG electrodes are required for reconstruction of image data).

Since PET-data are acquired continuously during the acquisition period while navigator signals are only obtained at the MR-repetition rate (in general one navigator for each individual measurement), only a fraction of the PET-data is acquired at navigator times. Thus, only a fraction of the acquired PET-data can be used for direct assignment of motion states to PET-data. Therefore, in a special variant of the inventive method, an interpolation between two sequential navigator times is carried out for determining an additional motion state (intermediate motion state) for a point in time between the two sequential navigator times. Thus, a higher temporal resolution can be obtained (provided that the motion pattern is known).

In another variant, a motion state is assigned to several sequential acquisition times. This variant can be applied e.g. during a breathing space in which a multitude of PET-data are acquired at several sequential acquisition times. By assigning a motion state to several sequential acquisition times, a higher number of data contribute to the PET-image, thus improving S/N-ratio.

The navigator signal can be part of an FID. I.e. the navigator signal comprises a partial region of the MR-signal without gradients, the nuclear spin system being rephased in this partial region.

Alternatively, the navigator signal can be an MR-echo-signal or part of a MR-echo-signal.

In a highly preferred variant, a read gradient is applied during detection of the MR-echo-signal. Different frequency components of the navigator signal can be assigned to the target regions, which are separated along the direction of the read gradient. Thus, spatial resolution of the navigator signal along the direction of the read gradient can be achieved within only one individual MR-measurement. Thus, the navigator signal gives information about the motion of target regions at different positions along the direction of the read gradient or about different bodies at different positions along the direction of the read gradient. By applying a read gradient during acquisition of the navigator signal, motion states of different target regions can be obtained by using only one common receiving coil.

Alternatively or in addition, a slice selection gradient can applied prior to determining the navigator signal. By applying a slice section gradient, a suitable area (navigator volume) of the body for generating the navigator can be chosen, which is sufficiently significant for the motion of the target region. The navigator volume does not necessarily contain parts of the target region (e.g. heart or lung of the body), but can be a part of the body which is influenced by the motion pattern (e.g. a cross section of an artery) of the target region. Applying a slice section gradient requires a longer time but offers an additional degree of freedom.

In case, no slice selection is applied (hard pulse), a broadband signal can be determined due to the short duration of the MR-individual measurements. Yet, if a hard pulse is used, surface coils should be used for determining motion states of torque-free motions (e.g. heartbeat). Method according to claim 1, characterized in that the navigator signal is an MR-echo-signal or part of an MR-echo-signal, wherein during detection of the MR-echo-signal a read gradient is applied and that a slice selection gradient is applied prior to determining the navigator signal.

A highly preferred variant combines applying a slice selection gradient prior to acquisition of the navigator signal(s) and applying a read gradient during acquisition of the navigator signal(s), whereby slice selection gradient and read gradient have different directions, in particular are perpendicular to each other. Thereby, determining navigator signals, which are spatially resolved in two directions, is enabled. Each spatially resolved navigator signal gives information about the motion of target regions at different positions within a body along the direction of the read gradient and/or the slice selection gradient or about target regions of different bodies at different positions along the direction of the read gradient and/or the slice selection gradient.

In a highly preferred variant, positron-emission tomography images of more than one body are generated simultaneously. The RF-excitation for the individual MR-measurements can be carried out with a single volume coil or with several surface coils.

The navigator signals for the different bodies can be determined via different receiving coils. By using separate receiving coils, in particular surface coils, for the different bodies (e.g. a coil array), separate navigator-signals can be determined for different bodies. The receiving coils are positioned such that one receiving coil detects MR-signals from one of the bodies and another receiving coil detects MR-signals from another body. Nuclear spins of both bodies can be excited simultaneously, e. g. by applying a hard pulse or a slice selective pulse, wherein the slice selection gradient is chosen such that the slice crosses both bodies.

In a preferred variant the navigator signals for the at least two bodies are detectedwith a single common receiving coil. In this case, it has to be figured out, which navigator signal (or which part of the navigator signal) is indicative for the motion of which body. In this respect, the invention provides several possible variants, as will be described later.

In a highly preferred variant, the navigator signal is an MR-echo-signal or part of an MR-echo-signal and a read gradient is applied with the individual MR-measurements and at least two of the bodies are separated along the direction of the read gradient. Nuclear spins of bodies, which are separated from each other along the direction of the read gradient, may be excited at the same navigator time. Different frequency components of the navigator signal can be assigned to the bodies, which are separated along the direction of the read gradient. Thus, spatial resolution of the navigator signal along the direction of the read gradient can be achieved within only one individual MR-measurement (only one excitation pulse has to be applied to acquire a navigator signal for several bodies). Thus, the motion states for several bodies can be determined for the same navigator time. This is a timesaving method for determining the motion states of several bodies.

Alternatively or in addition, a slice selection gradient can applied with the individual MR-measurements, wherein at least two of the bodies are offset along the direction of the slice selection gradient, and wherein for each of the offset bodies an individual MR-measurement is carried out. The slice selection gradients of the individual MR-measurements are chosen such that at any navigator time nuclear spins of only one of the two offset bodies are excited. Navigator signals for the bodies, which are offset in direction of the slice selection gradient, are acquired via different (successive) individual MR-measurements and thus, at different navigator times.

In order to assign each navigator signal to one of the offset bodies, the offset bodies do not necessarily need to be separated in the direction of the slice selection gradient but may also overlap in the direction of the slice selection gradient to some extent. Yet, in this case, it is necessary to ensure either that the bodies are displaced in direction of a read gradient or that the selected slice does not cross both bodies simultaneously. In order to assign each navigator signal to one of the offset bodies, the offset bodies do not necessarily need to be separated in the direction of the slice selection gradient but may also overlap in the direction of the slice selection gradient to some extent. Yet, in this case, it is necessary to ensure either that the bodies are displaced in direction of a read gradient or that the selected slice does not cross both bodies simultaneously.

A highly preferred variant combines applying a slice selection gradient prior to acquisition of the navigator signal(s) and applying a read gradient during acquisition of the navigator signal(s), whereby slice selection gradient and read gradient have different directions, in particular are perpendicular to each other. While the nuclear spins of only one body of a set of offset bodies, which are shifted relative to each other along the direction of the slice selection gradient, are excited, nuclear spins of several bodies of another set of bodies, which are separated from each other along the direction of the read gradient, can be excited at the same navigator time.

The direction of the slice selection gradients may be different for individual MR-measurements concerning different bodies. In this case, it might be necessary to adapt the direction of the read gradient (if applied) accordingly.

The individual MR-measurements for determining navigator signals for one of the offset bodies and individual MR-measurements for determining navigator signals for the other offset bodies are preferably carried out alternately Thus, the repetition time TR for the MR-measurements for a specific body is longer compared to determining a navigator signal for only one body, which results in a higher S/N-ratio.

MR-images can be generated in parallel to the PET-data acquisition.

### BRIEF DESCRIPTION OF THE DRAWINGS

FIG. 1 shows a schematic diagram of the components of a combined PET-imaging and MR-device for carrying out a method according to the invention.

FIG. 2 shows a body with a target region to be imaged and a navigator volume for acquiring navigator signals.

FIG. 3A schematically shows a first variant of an assignment of motion states determined from MR navigator signals of a respiratory motion pattern to PET data according to the invention.

FIG. 3B schematically shows a second variant of an assignment of motion states determined from MR navigator signals of a respiratory motion pattern to PET data according to the invention using interpolation.

FIG. 4A shows an MR pulse sequence for acquiring FID navigator signals.

FIG. 4B shows an MR pulse sequence for acquiring echo navigator signals.

FIG. 4C shows an MR pulse sequence for acquiring spatially resolved echo navigator signals.

FIG. 5 shows a coil-body arrangement for acquiring navigator signals with separate receiving coils for a set of bodies.

FIG. 6 shows a coil-body arrangement for acquiring navigator signals for a set of bodies offset in direction of a slice selection gradient and a set of bodies separated in direction of a read gradient by using spatially resolved navigator signals.

FIG. 7A shows a pulse sequence to be repeated to form the sequence of individual measurements for determining the navigator signals for the coil-body arrangement shown in Fig.

FIG. 7B shows the pulse sequence of FIG. 7A with an additional individual measurement for acquiring MR-image data.

### DETAILED DESCRIPTION

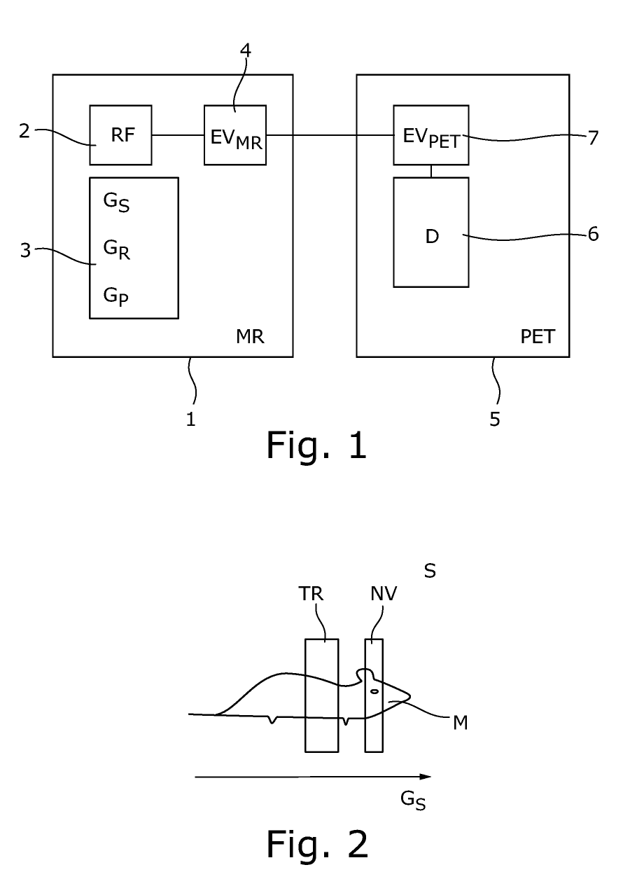

The inventive method combines PET-imaging with determination of motion states via MR navigator signal acquisition. An MR-device 1 is provided for determining the motion states. The MR-device 1 comprises an RF-system 2, a gradient-system 3 and an evaluation unit 4 for analyzing the navigator signals. For acquiring PET-imaging-data, a PET device 5 is provided. The PET device comprises a further evaluation unit 7 for receiving information concerning the motion states of the bodies at navigator times and for receiving the image data detected with a PET-detector 6, as shown in FIG. 1.

Using the MR-device, navigator signals are determined, which are indicative for the motion states of a motion pattern of a target region TR to be imaged (see FIG. 2). A gradient pulse sequence is applied to the body M via the gradient system 3. Nuclear spins of a navigator volume of the body M are excited by applying an excitation pulse with the RF-system 2 within a gradient pulse sequence.

The navigator volume NV can comprise the target region TR (e.g. heart or lung of the body) or parts of the target region TR. Alternatively, a navigator volume NV, which is different from the target region, can be chosen for acquiring navigator signals, as shown in FIG. 2. The navigator volume NV comprises a part of the body M, which is influenced by the motion pattern of the target region TR (e.g. an artery). In order to determine a navigator signal N(t), a responsive MR-signal is detected by the RF-system 2 of the MR-device 1. The navigator signal N(t) is analyzed with the evaluation unit 4, thereby determining the motion states of the target region TR of the body M. The determined motion states are related to navigator times (times at which nuclear spins of the body has been exited). For image reconstruction, PET-data detected at acquisition times within an acquisition period AP are linked with the motion states which correspond to the acquisition times of the image-data. The assignment of motion states to PET-data is carried out with the evaluation unit 4.

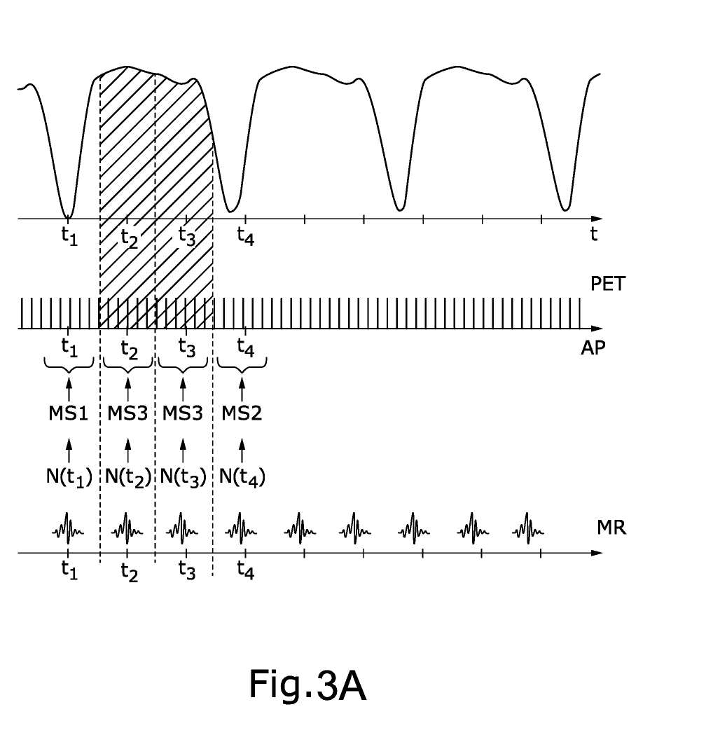

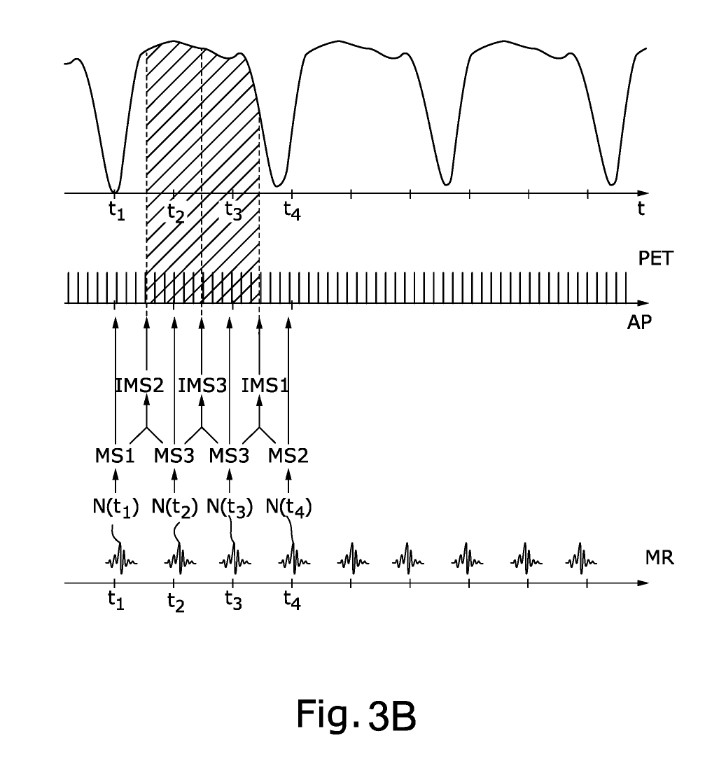

Different variants of the assignment process are illustrated in FIG. 3A, 3B for a respiratory motion pattern. Please note that the number of PET-data and MR-data within the shown respiratory motion pattern is not real but only for illustration purpose. At navigator times t1, t2, t3, t4 navigator signals N(t1), N(t2), N(t3), N(t4) are acquired. The navigator signals N(t1), N(t2), N(t3), N(t4) are analyzed, and motion states MS1 (inhalation), MS2 (exhalation), MS3 (breathing space) are determined from the navigator signals N(t1), N(t2), N(t3), N(t4). The determined motion states MS1, MS2, MS3 are assigned to PET-data acquired at the navigator times t1, t2, t3, t4.

In order to use not only PET-data which have been acquired exactly at navigator times tl, t2, t3, t4, but also PET-data, which have been acquired in between, a time interval At can be determined which can be added and/or subtracted from the navigator times t1, t2, t3, t4. The motion states MS1, MS2, MS3 can now be assigned to PET-data acquired within the respective time interval, as shown in FIG. 3a. I.e. a motion state determined from one navigator signal can be assigned to a multitude of PET-data. PET-data corresponding to a motion state of interest (here: breathing space MS3; crosshatched) can now be selected for PET-reconstruction.

In another variant, interpolation IP is used to determine intermediate motion states IMS1, IMS2, IMS3, which is shown by example in FIG. 3b. In this variant, motion states, which have been determined from navigator signals acquired at consecutive navigator times, can be used for interpolation IP in order to assign intermediate motion states IMS1, IMS2, IMS3 to acquisition times between the navigator times.

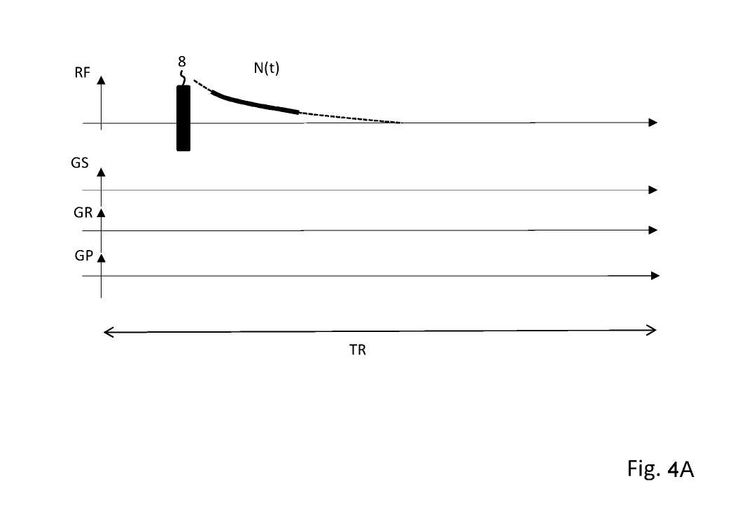

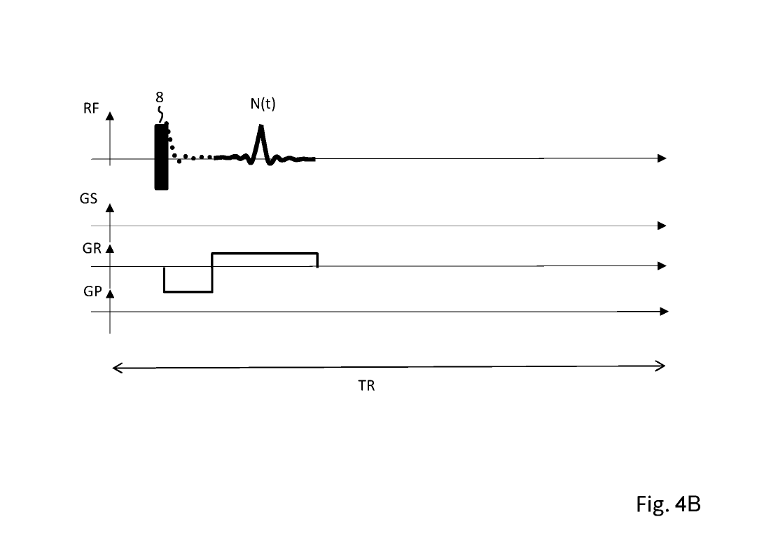

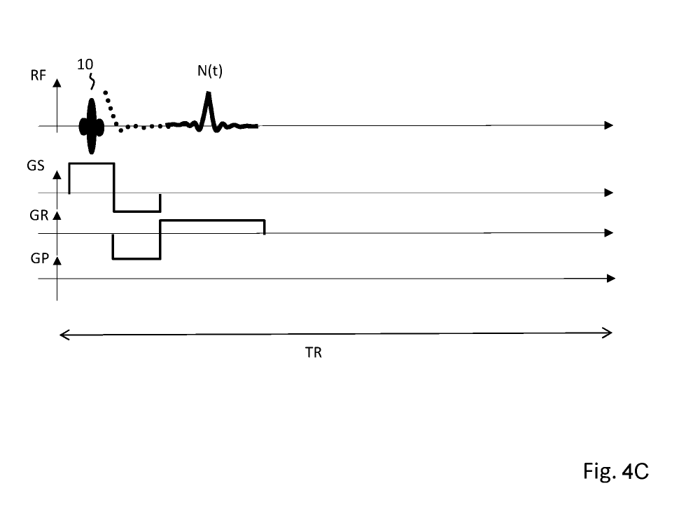

FIG. 4A-C show different gradient sequences for acquiring a navigator signal, wherein FID-data (FIG. 4A) and MR echo data (FIG. 4B, 4C) are acquired as navigator signals respectively. The navigator volume can be chosen by applying a slice section gradient G_{S} in combination with a tailored RF pulse 10 (see FIG. 4C). By omitting the slice selection gradient G_{S} and using a hard pulse 8 for excitation instead (FIG. 4A, 4B), the whole field of view of the receiving coil contribute to the navigator signal N(t).

Spatial resolution of the navigator signal N(t) within the navigator volume can be achieved by applying a read gradient G_{R} during acquisition of the navigator signal (see FIG. 4B, 4C).

The inventive method can also be applied to a multitude of target regions, in particular to a multitude of bodies to be simultaneously imaged by PET. In the following discussion the target region are situated within different bodies. Nevertheless, the described principle can also be applied to different target regions (e.g. heart, and lung) within one body.

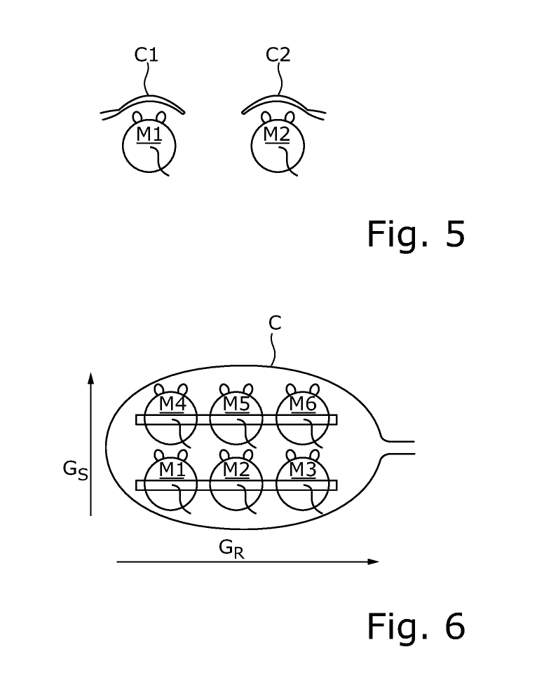

The motion states of the target regions/different bodies M1, M2 can be distinguished by using separate receiving coils C1, C2 for acquiring separate navigator signals for the target regions/different bodies M1, M2 , as shown in FIG. 5.

Other possibilities for distinguishing the motion states of the different target regions (here: different bodies M1, M2, M3, M4, M5, M6) is described in the following, wherein a common receiving coil can be used: FIG. 6 shows two first sets of bodies M1-M2-M3, M4-M5-M6, which are separated from each other in a first direction and three second sets of bodies M1-M4, M2-M5, M3-M6, which are separated in a second direction. In order to distinguish the motion states of the single bodies M1, M2, M3, M4, M5, M6, a read gradient G_{R} as well as a slice selection gradient G_{S} is applied, wherein the slice selection gradient G_{S} is applied in direction, in which one first set of bodies M1-M2-M3 is separated from the other first set of bodies M4-M5-M6, and the read gradient G_{R} is applied in direction, in which the second sets of bodies M1-M4, M2-M5, M3-M6 are separated from each other (or at least offset, i.e. the bodies do not necessarily need to be separated in the direction of the slice selection gradient, but may also overlap in the direction of the slice selection gradient to some extent as long as the non-overlapping regions reflect the motion states). Navigator signals N123(t); N456(t) are determined alternately, wherein different navigator volumes NV1, NV2 are selected by applying different excitation pulses 10, 10′ while applying a slice selection gradient G_{S} . Therefore, Navigator signals N123(t); N456(t) can be acquired from different navigator volumes along the slice selection gradient G_{S} . The navigator signal N123(t) is a common navigator signal for the first set of bodies M1-M2-M3 and the navigator signal N456(t) is common navigator signal for the other first set of bodies M4-M5-M6. Using frequency analysis the frequency components of the navigator signals N123(t), N456(t) of the respective first set of bodies M1-M2-M3, M4-M5-M6 can be separated due to the read gradient G_{R} which has been applied during detection of the MR-signal. Thus, each navigator signal N123(t), N456(t) is a spatially resolved navigator signal (in direction of the read gradient G_{R}). The number of frequencies regions, in which the navigator-signals N123(t), N456(t) is split, depends on the number of bodies within each first set of bodies M1-M2-M3, M4-M5-M6 (here: three). The number of individual measurements to be carried out for acquiring the navigator-signals N123(t), N456(t) depends on the number of bodies of each second set of bodies M1-M4, M2-M5, M3-M6 (here: two).

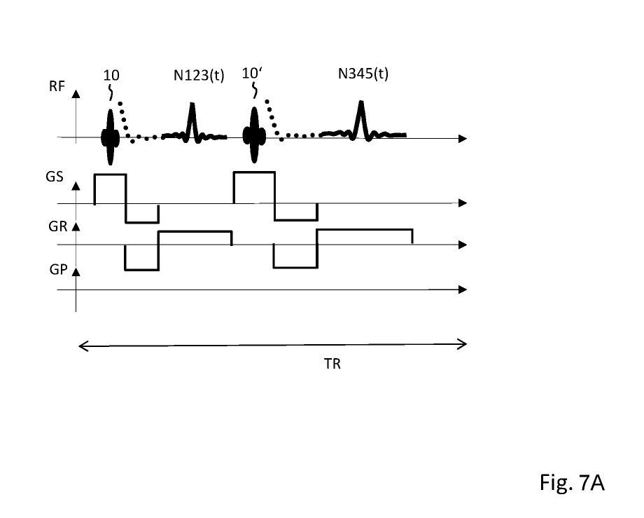

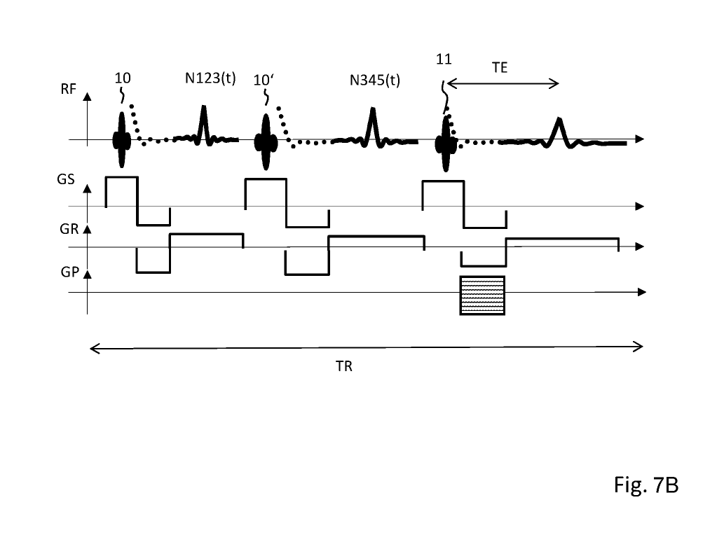

For the variant shown in FIG. 6 a sequence of individual MR measurements can be used in which a pulse and gradient sequence according to FIG. 7A is repeated. The pulse and gradient sequence according to FIG. 7A comprise two individual measurements for acquiring the navigator signals.

In addition to the acquisition of the navigator signals the MR-device 1 can be used for acquiring MR-image data in parallel to the PET-image data acquisition. For this purpose, a further individual MR-measurement for acquiring MR-image data can be added to the pulse and gradient sequence for acquiring the navigator signal(s), as shown in FIG. 7B. In FIG. 7B the pulse and gradient sequence comprise two individual measurements for acquiring navigator signals and a further individual MR-measurement for acquiring MR-image. Thus, MR-image data can be acquired from a target region which is different from the navigator volume.

### LIST OF REFERENCE SIGNS

1 MR-device
2 RF-system
3 gradient-system
4 evaluation unit of the MR-device
5 further imaging device (e.g. PET, CT)
6 PET-detector
7 further evaluation unit (evaluation unit of the further imaging device)
8 excitation pulse (hard pulse) for acquiring a navigator signal
10, 10′ tailored RF-pulse for acquiring a navigator signal
11 excitation RF-pulse for data acquisition
C receiving coil
C1, C2 surface coils
GR read gradient
GS slice selection gradient
IMS1, IMS2, IMS3 intermediate motion states
IP Interpolation
M1, M2, M3, M4, M5, M6 bodies
M1-M4, M2-M5, M3-M6 second sets of bodies
M1-M2-M3, M4-M5-M6 first sets of bodies
MS1, MS2, MS3 motion states
N(t) navigator signal N123(t) navigator signal indicative for motion states of bodies M1, M2 and M3
N456(t) navigator signal indicative for motion states of bodies M4, M5 and M6
NV navigator volumes
t1, t2, t3 navigator times
TR target region

What is claimed is:

1. Method for generating positron-emission tomography (PET) images of at least one body having a target region which is in an anatomic motion comprising a repetitive motion pattern with a motion repetition rate, comprising:
acquiring PET-data by performing a PET-measurement with a PET device during a PET-acquisition period;
determining motion states of the body during the PET-acquisition period; and
assigning the determined motion states to PET-data acquired at acquisition times; and
reconstructing PET-images from selected PET-data;
wherein, during the PET-acquisition period and with an MR device, a sequence of individual MR-measurements on the body is performed at a MR-repetition rate higher than the motion-repetition rate, wherein nuclear spins of the body are excited during the sequence of the individual MR-measurements at navigator times;
wherein, with the individual MR-measurements, navigator signals are determined, each navigator signal being indicative of a motion state of the motion pattern at the navigator time;
wherein the motion states are determined by analyzing the navigator signals, and
wherein the acquisition times to which the motion states are assigned correspond with the navigator times.

2. Method according to claim 1, wherein an interpolation between two sequential navigator times is carried out for determining an intermediate motion state for a point in time between the two sequential navigator times.

3. Method according to claim 1, wherein a motion state is assigned to several sequential acquisition times.

4. Method according to claim 1, wherein the navigator signal is part of an FID.

5. Method according to claim 1, wherein the navigator signal is an MR-echo-signal or part of an MR-echo-signal.

6. Method according to claim 5, wherein, during detection of the MR-echo-signal a read gradient is applied.

7. Method according to claim 1, wherein a slice selection gradient is applied prior to determining the navigator signal.

8. Method according to claim 1, wherein the navigator signal is an MR-echo-signal or part of an MR-echo-signal, wherein during detection of the MR-echo-signal a read gradient is applied, and wherein a slice selection gradient is applied prior to determining the navigator signal.

9. Method according to claim 1, wherein positron-emission tomography images of more than one body are generated simultaneously.

10. Method according to claim 9, wherein the navigator signals for the different bodies are determined with different receiving coils.

11. Method according to claim 9, wherein the navigator signals for the different bodies are determined with a single common receiving coil.

12. Method according to claim 11, wherein:
the navigator signal is an MR-echo-signal or part of an MR-echo-signal,
during detection of the MR-echo-signal, a read gradient is applied, and
at least two of the bodies are separated along the direction of the read gradient.

13. Method according to claim 11, wherein:
a slice selection gradient is applied prior to determining the navigator signal,
at least two bodies are offset along the direction of the slice selection gradient, and
for each of the offset bodies an individual MR-measurement is carried out, wherein the slice selection gradients of the individual MR-measurements are chosen such that at any navigator-time, nuclear spins of only one of the at least two offset bodies are excited.

14. Method according to claim 13, wherein the directions of the slice selection gradients are different for individual MR-measurements concerning different bodies.

15. Method according claim 13, wherein the individual MR-measurements for determining navigator signals for one of the offset bodies and individual MR-measurements for determining navigator signals for the other body are carried out alternately.

16. Method according to claim 1, wherein MR-images are generated in parallel to the PET-data acquisition.

17. Method according to claim 1, wherein the anatomic motion is cardiac and/or respiratory motion.
